(19) United States
(12) Patent Application Publication
(10) Pub. No.: US 2004/0042393 A1
(43) Pub. Date: Mar. 4, 2004

(54) Apparatus and method for data acquisition from network elements having reserved resources for specialized traffic

(76) Inventors: Muneyb Minhazuddin, New South Wales (AU); James D. Schreuder, New South Wales (AU)

Correspondence Address: John C. Moran, Attorney, P.C., 4120 E. 115th Place, Thornton, CO, 80233, US

(21) Appl. No.: 10/232,055

(22) Filed: Aug. 30, 2002

(51) Int. Cl. H04J 1/16; H04J 3/14; H04L 1/00; H04L 12/26; G01R 31/08

(52) U.S. Cl. 370/218

(57) ABSTRACT

An apparatus and method that automatically identifies problems on problem calls, periodically obtains data on network elements used for specialized traffic, and maintains a database on the capabilities of all network elements used for specialized traffic.

### TECHNICAL FIELD

The present invention relates to telecommunication systems and, in particular, to monitoring network elements utilized for the transmission of voice information.

### BACKGROUND OF THE INVENTION

Within the prior art, a well recognized problem in troubleshooting and monitoring packet networks that are transporting specialized data such as voice, for example Voice Over IP Networks (VoIP), is in identifying network elements that have caused a recent call to encounter problems. Within the prior art, the identification of such problems must be done by a field engineer and is normally done at a later point in time, unless the problems have been so sever that the field engineer is waiting for a problem to occur. In addition, to gather statistical information from the network elements, it is necessary for the field engineer to manually identify those elements carrying VoIP information, to periodically obtain this information, and collate the information.

### SUMMARY OF THE INVENTION

The aforementioned problems are solved and a technical advance is achieved in the art by an apparatus and method that automatically identifies problems on problem calls, periodically obtains data on network elements used for specialized traffic, and maintains a database on the capabilities of all network elements used for specialized traffic.

### BRIEF DESCRIPTION OF THE DRAWING

FIG. 1 illustrates an embodiment of an overall switching network comprising a plurality of network elements;

FIG. 2 illustrates an embodiment of the network elements remaining after the network elements that are switching only data are removed from FIG. 1;

FIGS. 3 and 4 illustrate, in flowchart form, operations performed by an embodiment of the invention;

FIG. 5 illustrates, in block diagram form, a maintenance terminal in accordance with an embodiment of the invention; and

FIG. 6 illustrates, in flowchart form, operations performed to determine the network elements of FIG. 2 from the network elements of FIG. 1.

### DETAILED DESCRIPTION

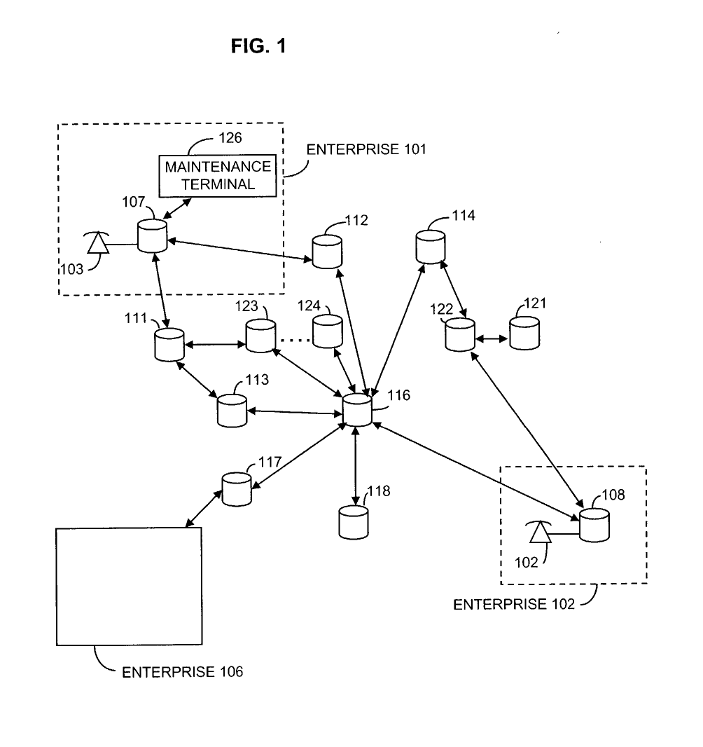

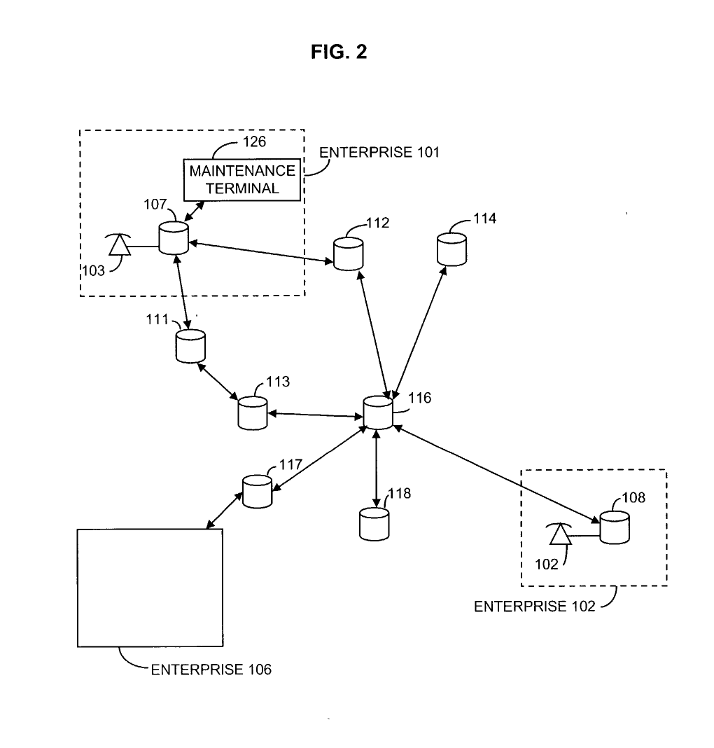

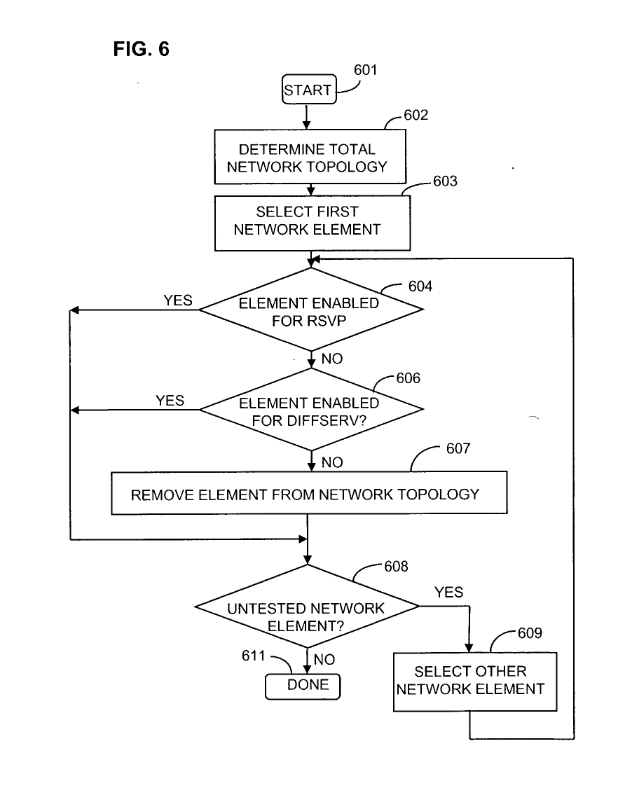

FIG. 1 illustrates a total network topology for a large entity voice and data switching system. For convenience, network elements 107, 108, and 111-119 are those that are designated to transport VoIP traffic. Although this example discusses only voice traffic, one skilled in the art could readily envision how to apply this example to video traffic or a combination of video and voice traffic. FIG. 2 illustrates the resulting network topology that remains for display purposes after all network elements that are transporting only data are removed from the network topology of FIG. 1. The removed network elements are not physically removed from the network. The operations required to extract FIG. 2 from FIG. 1 are discussed in greater detail with respect to FIG. 6.

In order to transport VoIP traffic through network elements, it is desirable to prioritize the real time traffic such as the VoIP traffic over the regular data traffic. The Internet Engineering Task Force has established the Resource Reservation Setup Protocol (RSVP) which is specification RFC 2205. RSVP is the quality of service mechanism commonly chosen for utilization within an office environment (one office building) to handle real time traffic such as VoIP traffic. Associated with the RSVP protocol is a Management Information Base (specification RSVP MIB RFC 2206). The MIB can be interrogated by the utilization of Simple Network Management Protocol (SNMP) inquiry messages to determine details of reserved flow parameters. The MIB variables provide the complete flow specification information for every traffic flow. Because of the large amount of data that is required for the RSVP MIB, the Internet Engineering Task Force has also defined the Differentiated Services Framework (DIFFSERV) specification RFC 2475. The DIFFSERV also allows for the prioritization of real time traffic such as VoIP traffic over other data types. Normally, the DIFFSERV protocol is used within the core of the network topology; whereas, the RSVP is used on the edges within individual enterprise sites. When a network is initially setup to handle VoIP traffic, a subset of the network elements are chosen by utilizing either RSVP or DIFFSERV protocol to handle the VoIP traffic. One skilled in the art could readily envision protocol other than RSVP and DIFFSERV that could be used to prioritize VoIP traffic over data traffic in the network elements.

One embodiment determines if problems have occurred within the network by monitoring to determine if there have been any problems on normal calls being placed through the network and by periodically interrogating each network element illustrated in FIG. 2 to obtain statistical data. If a network element is identified as causing serious problems, the embodiment first attempts to rectify the problem by re-provisioning the network element. If this is unsuccessful, the embodiment then attempts to find an alternate route around the network element causing the problems. If the embodiment is unable to resolve the problem, the embodiment visually indicates the problem to a field engineer and updates a database appropriately. The network elements are queried by utilizing the real time protocol (RTP) to access the database maintained by each network element. The querying accesses the delay, packet loss, jitter that has been experienced by packets being transmitted on specific links. The data extracted from the network elements is only for VoIP traffic.

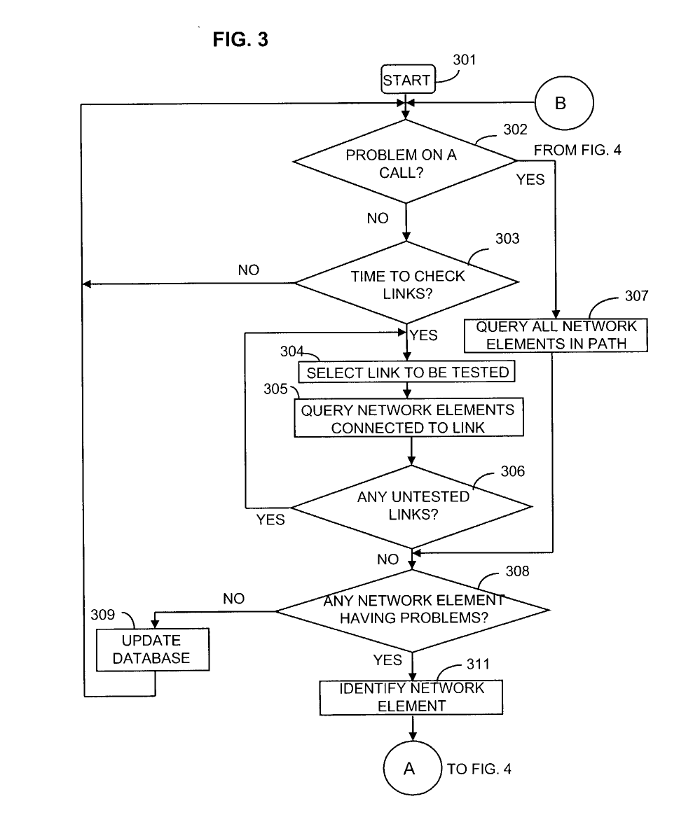

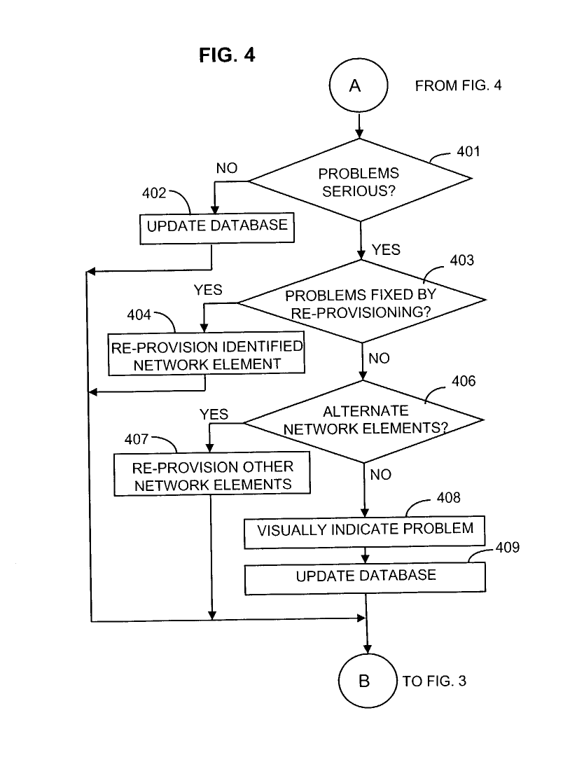

FIGS. 3 and 4 illustrate, in flowchart form, operations utilized to implement one embodiment of the invention. One skilled in the art would realize the operations illustrated in FIGS. 3 and 4 could be performed in other sequences or certain operations could be performed in parallel. Also in one embodiment, maintenance terminal 126 controls the operations of FIGS. 3 and 4. However, one skilled in the art would readily realize that other computer or hardware systems could be positioned in other parts of the network illustrated in FIGS. 1 and 2 for controlling the operations illustrated by FIGS. 3 and 4. After being started in block 301, block 302 determines if a problem has occurred on a recent call. If the answer is yes, control is transferred to block 307 which queries all network elements in the path of the call. After execution of block 307, control is transferred to block 308 which determines if any of the queried network elements were experiencing problems. If the answer is no in decision block 308, control is transferred to block 309 which updates the database and transfers control back to decision block 302.

If the answer is yes in decision block 308, block 311 identifies the network element experiencing the problem before transferring control to decision block 401 of FIG. 4. Decision block 401 determines if the problem or problems experienced by the network element are serious enough to require immediate remedies. If the answer is no, the database is updated to reflect the detection of a problem with the network element by block 402 before control is returned back to decision block 302 of FIG. 3.

If the answer in decision block 401 is yes, decision block 403 determines if the problem can be fixed by re-provisioning the network element. It may be that the network element had not been properly provisioned with sufficient band width, hence there was either excessive delay of the packets or packets were being lost because it was necessary to discard the packets. If this is the situation, decision block 403 transfers control to block 404. The latter block re-provisions the identified network element to overcome the problems that were identified before transferring control back to decision block 302 of FIG. 3.

If the answer in decision block 403 is no, control is transferred to decision block 406 which will attempt to determine if there is an alternate route around the identified network element that is experiencing the problems. This decision is made by accessing the database to determine the capacity and lack of problems in network elements that may be utilized for an alternate route. For example, if calls being placed from enterprise 201 of FIG. 2 are encountering problems on a path utilizing network elements 111, 113, and 116 to enterprise 102, an alternate route would be to utilize network element 112. Since the logic utilized by decision block 403 has the available network elements identified by FIG. 2 and the statistics for the various switch nodes maintained in the database, the decision can be made whether or not there is available an alternate route and what that route is.

If decision block 406 determines that there is an alternate route using other network elements, control is transferred to 407 which re-provisions the other network elements to take advantage of the alternate route before control is returned to decision block 302 of FIG. 3.

If the logic of decision block 403 and 406 are unable to rectify the problem being presented by the identified network element, block 408 visually indicates the problem network element to the field engineer. In one embodiment of the invention, it is envisioned that the diagram illustrated in FIG. 2 would be presented to the field engineer with the identified network element highlighted by being blinked on and off, etc. After the operation of block 408 is performed, control is transferred to block 409 which updates the database before returning control back to decision block 302 of FIG. 3.

Returning to decision block 302 of FIG. 3, if a problem has not been detected on a recent call, control is transferred to decision block 303 which determines if it is time to check all of the links illustrated in FIG. 2 for statistical data and to determine if any of the network elements interconnected by the links are experiencing problems. If the answer is no in decision block 303, control is transferred back to decision block 302. One skilled in the art would readily realize that it is not necessary for all links to be evaluated at one time but rather it is possible to do this on an ongoing basis where only a few links are checked for each occurrence of decision block 303.

If the answer in decision block 303 is yes, block 304 selects a link to be tested, and block 305 queries the network elements interconnected by that link. Decision block 306 then determines if there are any untested links. If the answer is yes, control is transferred back to block 304. If the answer in decision block 306 is no, control is transferred to decision block 308 whose operations have been previously described.

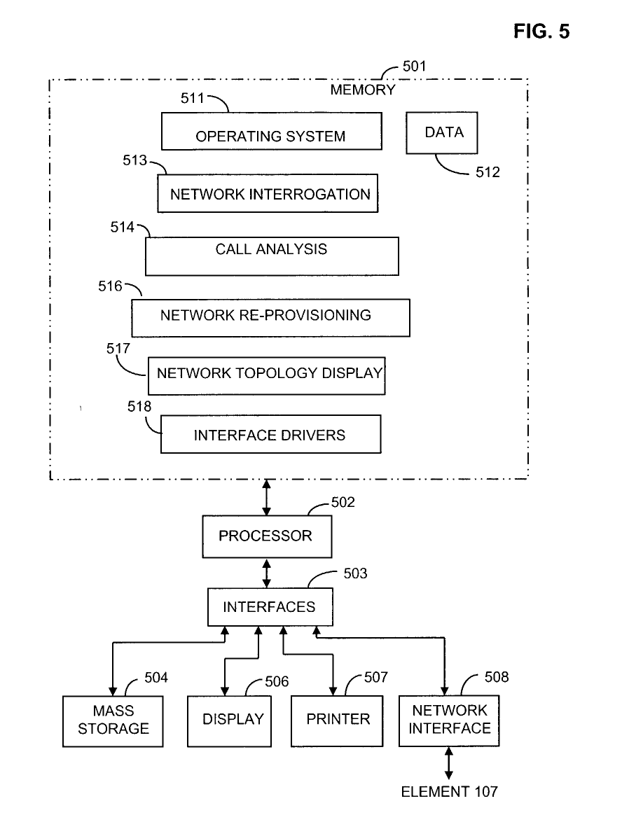

FIG. 5 illustrates, in block diagram form, greater detail of maintenance terminal 126 of FIGS. 1 and 2. Overall control of the maintenance terminal is provided by processor 502 executing instructions from memory 501 and storing and retrieving data within memory 501. Instruction and data may be also stored within mass storage 504. Processor 502 is interconnected to peripheral devices 504-508 via interfaces 503. Display 506 allows processor 501 to display information to a user, and printer 507 allows information to be printed out for the user. Network interface 508 provides the interconnection to switching element 107 of enterprise 101. One skilled in the art would readily realize that maintenance terminal 126 could be connected to any switching element of the network illustrated in FIGS. 1 and 2.

Operating system 511 provides the overall control of the software functions performed by processor 502. Routines 513-517 provide the operations as illustrated in FIGS. 3 and 4 in accordance with one embodiment. Interface drivers 518 provide the necessary support for peripheral units. Although not illustrated in FIG. 5, one skilled in the art would readily realize that other routines and applications would be executed by processor 502 for various functions. Network interrogation routine 513 provides the function of interrogating the network elements of the network and determining switching information from these network elements. Call analysis routine 514 is utilized to detect and analyze call problems. Network topology display routine 517 is used to display topologies such as FIGS. 1 and 2 on display 506 or printer 507. Network re-provisioning routine 516 is utilized to analyze and re-provision network elements.

The operations of maintenance terminal 126 can be implemented in software, hardware, or a combination thereof. In the currently contemplated best mode, the operations of maintenance terminal 126 of FIG. 5 are implemented in software, as an executable program, that is executed by processor 502. Processor 502 is a hardware device for executing software, particularly that stored in memory 501. Processor 502 can be any custom made or commercially available processor.

The memory 501 can include any one or combination of volatile memory elements (e.g., random access memory (RAM, such as DRAM, SRAM, SDRAM, etc.) and nonvolatile memory elements (e.g., ROM, hard drive, tape, CDROM, etc.). Moreover, the memory 501 may incorporate electronic, magnetic, optical, and/or other types of storage media. Note, that the memory 501 can have a distributed architecture, where various components are situated remote from one another, but can be accessed by processor 502.

When the operations of maintenance terminal 126 are implemented in software, as is shown in FIGS. 3 and 4, it should be noted that the software can be stored on any computer-readable medium for use by or in connection with any computer related system or method. In the context of this document, a computer-readable medium is an electronic, magnetic, optical, or other physical device or means that can contain or store a computer program for use by or in connection with a computer related system or method. Maintenance terminal 126 can be embodied in any computer-readable medium for use by or in connection with an instruction execution system, apparatus, or device such as a computer-based system, processor-containing system, or other system that can fetch the instructions from the instruction execution system, apparatus, or device and execute the instructions. In the context of this document, a “computer-readable medium” can be any means that can store, communicate, propagate, or transport the program for use by or in connection with the instruction execution system, apparatus, or device. For example, the computer-readable medium can be, but is not limited to, an electronic, magnetic, optical, electromagnetic, infrared, or semiconductor system, apparatus, device, or propagation medium. More specific examples (a non-exhaustive list) of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM, EEPROM, or Flash memory) (electronic), an optical fiber (optical), and a portable compact disc read-only memory (CDROM) (optical). Note that the computer-readable medium could even be paper or another suitable medium upon which the program is printed, as the program can be electronically captured, for instance, via optical scanning of the paper or other medium, then compiled, interpreted or otherwise processed in a suitable manner if necessary, and then stored in a computer memory.

In an alternative embodiment, where maintenance terminal 126 is implemented in hardware, maintenance terminal 126 can be implemented with any or a combination of the following technologies, which are each well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

FIG. 6 illustrates, in flowchart form, the operations utilized to extract FIG. 2 from FIG. 1. One skilled in the art would realize the operations illustrated in FIG. 6 could be performed in other sequences or certain operations could be performed in parallel. Also in one embodiment, maintenance terminal 126 controls the operations of FIG. 6. However, one skilled in the art would readily realize that other computer or hardware systems could be positioned in other parts of the network illustrated in FIGS. 1 and 2 for controlling the operations illustrated by FIG. 6. After being started in block 601, block 602 determines the total network topology which includes not only the network elements within the network but the manner in which these network elements are interconnected. One skilled in the art would readily realize that one approach is simply to interrogate in a fairly random manner each network element illustrated in FIG. 1 to determine how this network element is connected to other network elements. However, such a brute force method requires a great deal of time to accomplish. Advantageously, a faster and more efficient method of determining the network topology such as illustrated in FIG. 1 is set forth in the U.S. patent application entitled “Using Link State Information to Discover IP Network”, Ser. No. 10/127967 filed on Apr. 22, 2002, Attorney Docket No. 401046-A-01-US (Goringe) and U.S. patent application entitled “Topology Discovery by Partitioning Multiple Discovery Techniques”, Ser. No. 10/127888 filed on Apr. 26, 2002, Attorney Docket No. 401059-A-01-US (Goringe). These two patent applications are hereby incorporated herein by reference. Utilizing either the brute force method of the prior art or the method set forth in the two patent applications, block 602 determines the network topology illustrated in FIG. 1. One skilled in the art would readily realize that if other network topologies were being analyzed by the methods utilized in block 602 that other topology illustrations would result.

Once a total network topology is determined such as illustrated in FIG. 1, blocks 603-609 then conceptually remove from this overall network topology all network elements that are set up to prioritize real time traffic such as VoIP traffic over other data traffic. The resulting topology that is displayed to the field engineer illustrates only elements 107,108, and 111-119. Note, that the remaining blocks are not physically removed from the network of FIG. 1. Block 603 selects an element from FIG. 1 such as element 111. Block 604 then determines if this network element is enabled for RSVP by transmission of a SNMP message to network element 111 inquiring whether or not it is set up for the RSVP protocol. If the answer is yes, control is transferred to decision block 608. If the answer in decision block 604 is no, a second SNMP message is transmitted to network element 111 inquiring whether it is setup for the DIFFSERV protocol. In the present example, network element 111 is utilizing either the RSVP or DIFFSERV protocol SO control will be transferred from either decision block 604 or decision block 606 to decision block 608. Decision block 608 determines if there are any remaining untested network elements. Since network element 111 was the first network element tested, the answer in decision block 608 is yes, and control is transferred to block 609 that selects another network element for testing of the network elements of FIG. 1.

For the present example, assume that the other network element is network element 121. Control is transferred from block 609 back to decision block 604. Decision blocks 604 and 606 transmits SNMP messages to network element 129 inquiring whether it is implementing the RSVP or DIFFSERV protocol. Since in the present example the answer is no, control is transferred from decision block 606 to block 607. Utilizing well known graphical techniques to those skilled in the art, block 607 removes network element 129 from the displayed network topology illustrated in FIG. 1. After the network element is removed, block 608 transfers control to block 609 that selects another network element before transferring control back to decision block 604. After it is determined by decision block 608 that all network elements of FIG. 1 have been tested, the process is ended by execution of block 611. The resulting network topology is illustrated in FIG. 1 and contains only those network elements that are implementing either the RSVP protocol or the DIFFSERV protocol.

Of course, various changes and modifications to the illustrated embodiments described above will be apparent to those skilled in the art. These changes and modifications can be made without departing from the spirit and scope of the invention and without diminishing its intending advantages. It is therefore intended that such changes and modifications be covered by the following claims except insofar as limited by the prior art.

What is claimed is:

1. A method for acquiring information from network elements, comprising the steps of:
determining a subset of network elements that are communicating specialized data;
periodically obtaining transmission parameters from each of the subset of network elements;
storing obtained transmission parameters in a database;
analyzing the obtained transmission parameters to identify ones of the subset of network elements that may cause transmission problems; and
re-provisioning the identified ones of the subset of network elements to eliminate the transmission problems.

2. The method of claim 1 further comprises the step of modifying transmission routes through the subset of network elements to eliminate the transmission problems using the database.

3. The method of claim 1 wherein the step of re-provisioning comprises the step of increasing the bandwidth of the ones of the subset of network elements for the communicating the specialized data.

4. The method of claim 1 wherein the transmission parameters are at least one of delay, packet loss, or jitter.

5. The method of claim 1 wherein the step of obtaining comprises the step of requesting the transmission parameters from each of the subset of network elements.

6. The method of claim 1 wherein the specialized data is encoded voice information.

7. The method of claim 1 wherein the specialized data is encoded video information.

8. A method of detecting problems in transmission of specialized data via network elements, comprising the steps of:
determining problems on a call using the specialized data;
determining a subset of the network elements transporting the call;
obtaining transmission parameters from each of the subset of network elements;
storing obtained transmission parameters in a database;
analyzing the obtained transmission parameters to identify ones of the subset of network elements that may cause transmission problems; and
determining a second subset of network elements that are communicating specialized data; and
modifying transmission route of the call through the second subset of network elements to eliminate the transmission problems using the database.

9. The method of claim 8 further comprises the step of re-provisioning the identified ones of the subset of network elements to eliminate the transmission problems of the call.

10. The method of claim 8 wherein the step of re-provisioning comprises the step of increasing the bandwidth of the ones of the subset of network elements for the communicating the specialized data.

11. The method of claim 8 wherein the transmission parameters are at least one of delay, packet loss, or jitter.

12. The method of claim 8 wherein the step of obtaining comprises the step of requesting the transmission parameters from each of the subset of network elements.

13. The method of claim 8 wherein the specialized data is encoded voice information.

14. The method of claim 8 wherein the specialized data is encoded video information.

15. A processor-readable medium comprising processor-executable instructions configured for acquiring information from network elements, comprising:
determining a subset of network elements that are communicating specialized data;
periodically obtaining transmission parameters from each of the subset of network elements;
storing obtained transmission parameters in a database;
analyzing the obtained transmission parameters to identify ones of the subset of network elements that may cause transmission problems; and
re-provisioning the identified ones of the subset of network elements to eliminate the transmission problems.

16. The processor-readable medium of claim 15 further comprises modifying transmission routes through the subset of network elements to eliminate the transmission problems using the database.

17. The processor-readable medium of claim 15 wherein re-provisioning comprises increasing the bandwidth of the ones of the subset of network elements for the communicating the specialized data.

18. The processor-readable medium of claim 15 wherein the transmission parameters are at least one of delay, packet loss, or jitter.

19. The processor-readable medium of claim 15 wherein obtaining comprises requesting the transmission parameters from each of the subset of network elements.

20. The processor-readable medium of claim 15 wherein the specialized data is encoded voice information.

21. The processor-readable medium of claim 15 wherein the specialized data is encoded video information.

22. A processor-readable medium comprising processor-executable instructions configured for detecting problems in transmission of specialized data via network elements, comprising:
determining problems on a call using the specialized data;
determining a subset of the network elements transporting the call;
obtaining transmission parameters from each of the subset of network elements;
storing obtained transmission parameters in a database;
analyzing the obtained transmission parameters to identify ones of the subset of network elements that may cause transmission problems; and
determining a second subset of network elements that are communicating specialized data; and
modifying transmission route of the call through the second subset of network elements to eliminate the transmission problems using the database.

23. The processor-readable medium of claim 22 further comprises re-provisioning the identified ones of the subset of network elements to eliminate the transmission problems of the call.

24. The processor-readable medium of claim 22 wherein re-provisioning comprises increasing the bandwidth of the ones of the subset of network elements for the communicating the specialized data.

25. The processor-readable medium of claim 22 wherein the transmission parameters are at least one of delay, packet loss, or jitter.

26. The processor-readable medium of claim 22 wherein obtaining comprises requesting the transmission parameters from each of the subset of network elements.

27. The processor-readable medium of claim 22 wherein the specialized data is encoded voice information.

28. The processor-readable medium of claim 22 wherein the specialized data is encoded video information.
